(19) United States
(12) Patent Application Publication
(10) Pub. No.: US 2026/0086143 A1
(43) Pub. Date: Mar. 26, 2026

(54) COMMUNICATING WITH A DUT FOR TESTING

(71) Applicant: Teradyne, Inc., North Reading, MA (US)

(72) Inventors: Jason Messier, Winchester, MA (US); Gregory C. Warwar, Moorpark, CA (US); Jeffrey Benagh, Melrose, MA (US)

(73) Assignee: Teradyne, Inc., North Reading, MA (US)

(21) Appl. No.: 18/894,606

(22) Filed: Sep. 24, 2024

(51) Int. Cl. G01R 31/28

(52) U.S. Cl. CPC G01R 31/2844

(57) ABSTRACT

An example apparatus is configured to communicate with a device under test (DUT). The apparatus includes a first interface circuit to communicate with a test instrument using a first protocol and a second interface circuit to communicate with the DUT using a second protocol. The second protocol is a predefined protocol for which the DUT is configured to operate. The first protocol is for connections associated with a first frequency attenuation. The second protocol is for connections associated with a second frequency attenuation. The first frequency attenuation is greater than the second frequency attenuation. Circuitry is configured to perform one or both of the following operations: (i) converting first data received from the test instrument in the first protocol to the second protocol for output to the DUT via the second interface circuit, or (ii) converting second data received from the DUT in the second protocol to the first protocol for output to the test instrument via the first interface circuit.

### TECHNICAL FIELD

This specification describes example implementations of techniques for communicating with a device under test (DUT) in order to test the DUT.

### BACKGROUND

A test system is configured to test the operation of a device. A device tested by a test system is referred to as a device under test (DUT). Signal frequency attenuation can be an issue when testing a DUT. Signal frequency attenuation may be a function of the distance between the DUT and the test system. For example, signal frequency attenuation may increase at greater distances between a test instrument and the DUT. This can affect the accuracy of the testing performed on the DUT.

### SUMMARY

An example apparatus is configured to communicate with a device under test (DUT). The apparatus includes a first interface circuit to communicate with a test instrument using a first protocol and a second interface circuit to communicate with the DUT using a second protocol. The second protocol is a predefined protocol for which the DUT is configured to operate. The first protocol is for connections associated with a first frequency attenuation. The second protocol is for connections associated with a second frequency attenuation. The first frequency attenuation is greater than the second frequency attenuation. Circuitry is configured to perform one or both of the following operations: (i) converting first data received from the test instrument in the first protocol to the second protocol for output to the DUT via the second interface circuit, or (ii) converting second data received from the DUT in the second protocol to the first protocol for output to the test instrument via the first interface circuit. The apparatus may include one or more of the following features, either alone or in combination.

The first frequency attenuation may be based on an S21 parameter associated with the test instrument and the second frequency attenuation may be based on an S21 parameter associated with the DUT. The first frequency attenuation may be an order of magnitude greater than the second frequency attenuation. Connections associated with a first frequency attenuation have a length of one meter (m) or more and connections associated with a second frequency attenuation have a length of 30 centimeters (cm) or less. Connections associated with a first frequency attenuation have a length of one meter (m) or more and connections associated with a second frequency attenuation have a length of 3 centimeters (cm) or less.

The circuitry may be programmable. The circuitry may be programmed to perform conversions between the first protocol and the second protocol. The circuitry may be or include one or more of a microprocessor or programmable logic. The circuitry may include multiple analog to digital converters. The circuitry may include a serializer/deserializer circuit configured to convert parallel second data to serial first data. The circuitry may be configured to perform one of more operations on at least one of the first data or the second data, where the one or more operations may include: payload extraction, data aggregation, or frame averaging.

The apparatus may be part of a probe card configured to electrically connect to electrical pins on the DUT. The apparatus may be a needle of a probe card configured to electrically connect to an electrical pin on the DUT.

The second protocol may be MIPI (Mobile Industry Processor Interface). The second protocol may be UCIe (Universal Chiplet Interconnect Express). The second protocol may be a radio frequency (RF) protocol.

The apparatus may include a switch configured to connect to a parametric measurement unit (PMU) configured to measure one or more properties of a signal. The apparatus may include the PMU.

The apparatus may be a package. The package may include a first silicon module including the first interface, the second interface, the circuitry, and the switch; and a second silicon module including the PMU.

An example method includes performing at least one of the following first operations or the following second operations. The first operations include: receiving, at a first interface circuit, first data from a test instrument, where the first data has a first protocol; converting the first data having the first protocol into first data having a second protocol, where the second protocol is a known protocol, the first protocol is for connections associated with a first frequency attenuation, the second protocol is for connections associated with a second frequency attenuation, and the first frequency attenuation is greater than the second frequency attenuation; and outputting, via a second interface circuit, the first data having the second protocol to a device under test (DUT). The second operations include receiving, at the second interface circuit, second data from the DUT, where the second data has the second protocol; converting the second data having the second protocol into second data having the first protocol; and outputting, via the first interface circuit, the second data having the first protocol to the test instrument. The method may include one or more of the following features, either alone or in combination.

The first frequency attenuation may be based on an S21 parameter associated with the test instrument and the second frequency attenuation may be based on an S21 parameter associated with the DUT. The first frequency attenuation may be an order of magnitude greater than the second frequency attenuation. Connections associated with a first frequency attenuation have a length of one meter (m) or more and connections associated with a second frequency attenuation have a length of 30 centimeters (cm) or less. Connections associated with a first frequency attenuation have a length of one meter (m) or more and connections associated with a second frequency attenuation have a length of 3 centimeters (cm) or less.

The first interface circuit and the second interface circuit may be on a probe or probe needle. The method further may include bringing at least part of the probe or the probe needle into electrical contact with the DUT.

Any two or more of the features described in this specification, including in this summary section, may be combined to form implementations not specifically described in this specification.

At least part of the devices, systems, circuits, and processes described in this specification may be configured or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, circuits, and processes described in this specification may be configured or controlled using a computing system comprised of one or more processing devices and memory storing instructions that are executable by the one or more processing devices to perform various control operations. The devices, systems, circuits, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a block diagram of an example test system.

FIG. 2 is a block diagram of an example configuration of components of the example test system.

FIG. 3 is a block diagram of another example configuration of components of the example test system.

FIG. 4 is a flowchart showing example operations included in an example process for communicating to a device under test (DUT) for testing.

FIG. 5 is a flowchart showing example operations included in an example process for communicating from a DUT during testing.

Like reference numerals in different figures indicate like elements.

### DETAILED DESCRIPTION

Described herein are examples of systems and processes for communicating with a device under test (DUT) to test the DUT. The DUT may be any type of electronic device such as, but not limited to, a microprocessor, a graphics processing unit (GPU), or a radio frequency (RF) transceiver configured to implement wireless communications such as cellular, WiFi, Bluetooth, or GPS (global positioning system) functionality.

The example systems and processes communicate with the DUT using a long-haul connection and a short-haul connection, with circuitry to convert between the two. The long-haul connection may be on the order of single-digit meters or more (for example, one meter or more). The short-haul connection may be on the order of double-digit centimeters or less (for example, 30 centimeters (cm) or less) or single-digit centimeters or less (for example 5 cm or less, 4 cm or less, 3 cm or less, 2 cm or less, or 1 cm or less).

In some examples, the long-haul connection uses a communication protocol and includes equalization or other processing to produce a high-bandwidth link between the DUT and the test instrument, thereby addressing frequency attenuation in signals that may occur over long-haul connections and allowing data to be transferred over the long haul connection with a relatively low frequency attenuation. Frequency attenuation includes a loss of signal strength. In some examples, a relatively low frequency attenuation enables a bit error rate (BER) of 10⁻¹⁵ or less. In some examples, in this context, a relatively large frequency attenuation is at least an order of magnitude greater than a relatively small frequency attenuation.

In some examples, the short-haul connection does not include such equalization or other processing; however, due to the relatively short distance, frequency attenuation does not have a considerable deleterious effect on the data, resulting in BERs on the short-haul connection that are comparable to, or better than, the BERs of the long-haul connection. As such, protocols used over short-haul connections may have relatively few or no features designed to address frequency attenuation.

Different protocols may be used to transmit the data over the long-haul connection and the short-haul connection. For example, protocols configured for connections that, absent use of such protocol(s), would produce relatively large frequency attenuations may be used for communications over a long-haul connection. Protocols associated with (e.g., that address) relatively large frequency attenuations include, but are not limited to, one or more of the following protocols: PCIe5/6 (peripheral component interconnect express) and Ethernet. For example, protocols configured for connections having relatively small frequency attenuations may be used for communications over a short-haul connection. Protocols associated with relatively small frequency attenuation include, but are not limited to, one or more of the following protocols: the mobile industry processor interface (MIPI®) protocol, the common flash interface (CFI) protocol, the DFI (DDR PHY Interface) protocol, the MFI (made for iPhone®/iPod®/iPad®) protocol, the UCIe (universal chiplet interconnect express) protocol, and/or one or more RF protocols.

The frequency attenuation over the long-haul connection may be based on an S21 parameter associated with the test instrument and the frequency attenuation over the short-haul connection may be based on an S21 parameter associated with the DUT.

The c-phy v2.1 standard has a channel mask that tolerates an S21 parameter of −4.85+/−0.55 dB (decibels) at 5 Ghz (gigaherz). The S21 parameter of a channel going directly to test equipment has an S21 parameter of about −18.1 dB at 5 Ghz. Thus, in some implementations, the maximum baud rate at a reasonable BER is lower than the maximum baud rate allowed using a compliant channel S21.

Circuitry, such as one or more processing devices or programmable logic, is configured to perform conversion between a first protocol that is used for communication to and from the test instrument over the long-haul connection and a second protocol, which is different from the first protocol, that is used for communication to and from the DUT over the short-haul connection. The circuitry thus may enable communications directly to the DUT to be implemented without the equalization or other processing required for long-haul connections and protocols. The circuitry also may enable communications directly to the DUT in protocol(s) actually used by the DUT for short-range, lower frequency-attenuation, communications.

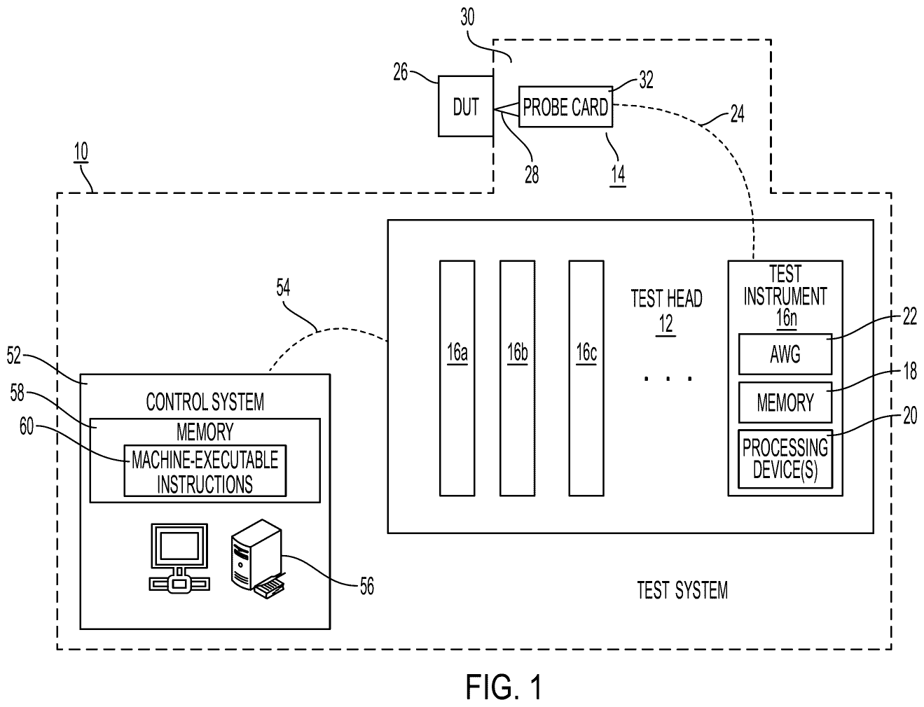

FIG. 1 is a block diagram showing example components of example test system 10, which may be automatic test equipment (ATE), that may be used to implement all or part of the system and processes described herein. Test system 10 includes a test head 12, which may be in wired or wireless communication with a probe card 14.

In this example, test head 12 includes multiple test instruments 16a to 16n (where n>3), each of which may be configured, as appropriate, to implement testing as described herein and/or other functions. Although only four test instruments are shown, test system 10 may include any appropriate number of test instruments, including one or more residing outside of test head 12. The test instruments may be hardware devices that each may include memory 18, one or more processing devices 20, an automatic waveform generate (AWG) 22, and/or other circuitry (not shown). These components are illustrated only on test instrument 16n.

The test instruments may be configured—for example, programmed—to generate and to output test signals containing test data. For example, memory 18 may store instructions for a test program that are executable by processing devices 20 to control AWG 22 to output test signals over long-haul connection 24 on a path to DUT 26. The test signals may be high-frequency signals, examples of which includes signals in the gigabit-per-second range (Gb/s). Long-haul connection 24 may include a wired connection, such as one or more coaxial cables, Ethernet, or other transmission media, and may have lengths and frequency attenuations that produce BERs similar to those described above. Long-haul connection 24 may include a wireless, e.g., RF connection. Long-haul connection 24 may electrically connect to probe card 14, thereby enabling communication between probe card 14 and test instrument 16n.

Only one probe card and DUT are shown in FIG. 1. However, there may be multiple probe cards (not shown) and corresponding DUTs (not shown) connected to one, some, or all of test instruments 16a to 16n. These multiple probe cards may have the same, or different, structure and function as example probe card 14.

Test instrument 16n is also configured to receive response signals containing response data over long-haul connection 24. Response signals may include data based on a DUT 26's response to the test data provided by AWG 22. Test instrument 16n may be configured to process those response signals to determine if DUT 26 passed or failed testing. For example, one or more processing devices 20 on test instrument 16n may execute instructions from memory 18 to compare the response data received from probe card 14 to one or more thresholds and to determine, based on the comparison, whether DUT 26 passed or failed testing.

Example probe card 14 is physically movable to within double-digit or single-digit centimeters of, or single-digit millimeters of, DUT 26 in order to enable testing of DUT 26. For example, probe card 14 may include a needle 28 configured to contact a pin on DUT 26 to provide test data to that pin and to receive response data from that pin. Needle 28 includes electrically conductive material, such as metal (e.g., copper or aluminum) to create an electrical connection between probe card 14 and DUT 26. Needle 28 may be a MEMS (micro-electromechanical system) probe needle.

Data is sent between the probe card and the DUT over short-haul connection 30 using a protocol configured for connections that produce relatively low frequency attenuation, examples of which are described herein. Short-haul connection 30 may include a conductive connection, which may be or include needle 28 and/or an electrically conductive portion of needle 28 on probe card 14. Short-haul connection 30 may have a length and produce a frequency attenuation that produce BERs similar to those described above. Short-haul connection 30 may include a wireless, e.g., RF connection.

Example probe card 14 may include a substrate 32 in addition to needle 28. Substrate 28 may include circuitry and conductive traces (not shown) to receive and to process data for output over long-haul connection 24 to test instrument 16a.

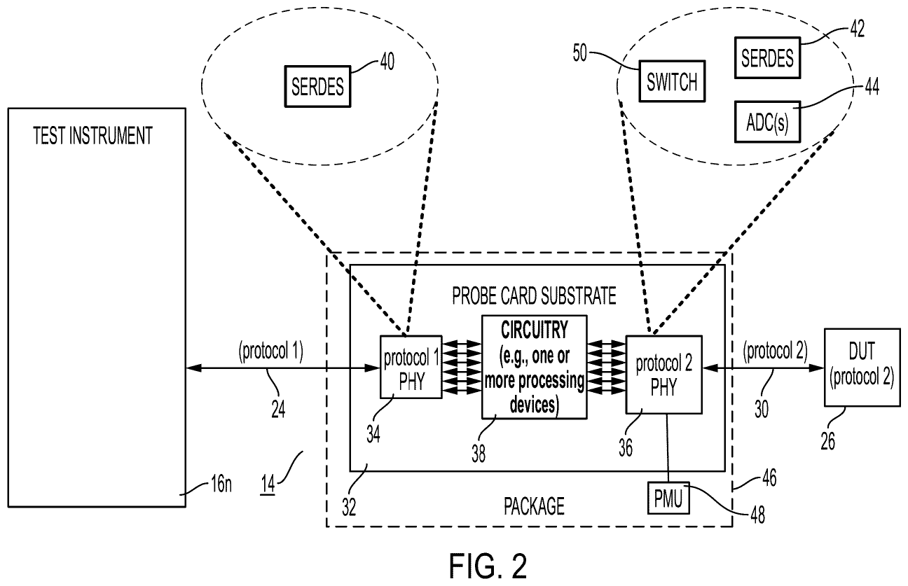

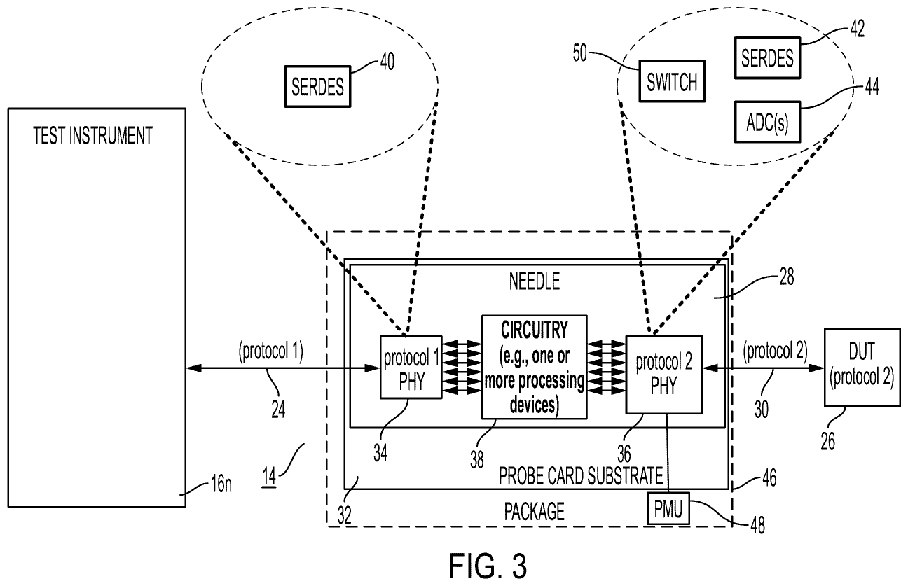

Referring to FIGS. 2 and 3, example probe card 14 includes a first interface circuit 34, a second interface circuit 36, and circuitry 38 to convert data between protocols used by first interface circuit 34 and second interface circuit 36 to communicate, respectively, with test instrument 16n and DUT 26. In the example of FIG. 2, these components are on substrate portion 32 of probe card 14. In the example of FIG. 3, these components may be on a needle portion 28 of probe card 14.

First interface circuit 34 and a second interface circuit 36 may include physical (PHY) interfaces to long-haul connection 24 and short-haul connection 30, respectively. First interface circuit 34 communicates with test instrument 16n over long-haul connection 24. The communications use a protocol, such as those described above, designed for connections that produce, absent use of such protocol(s), relatively large frequency attenuations in signals, which may be due to the relatively long length of the communications medium and/or relatively long distance between first interface circuit 34 and the test instrument 16n. Second interface circuit 36 communicates with DUT 26 over short-haul connection 30. The communications use a different protocol, such as those described above, designed for connections that produce relatively small frequency attenuations in signals, which may be due to the relatively short length of the communications medium and/or relatively short distance between second interface 36 circuit and DUT 26.

Circuitry 38 may include one or more processing devices, one or more instances of programmable logic, and/or one or more solid state electronic devices. Circuitry 38 is configured to perform conversion between the protocol that is used for communication to and from the test instrument over the long-haul connection and the protocol that is used for communication to and from the DUT over the short-haul connection. To this end, circuitry 38 is configured to perform one or both of the following operations: (i) converting data received from test instrument 16n a first (long-haul) protocol to a second (short-haul) protocol for output to DUT 26 via second interface circuit 36, or (ii) converting data received from DUT 26 in the second (short-haul) protocol to the first (long-haul) for output to test instrument 16n via first interface circuit 34. In some cases, the conversion process may include payload extraction, data aggregation, frame averaging, and/or one or more other operations not listed.

In some implementations, as shown in FIGS. 2 and 3, communications between first interface circuit 34 and test instrument 16n are serial communications; and communications between second interface circuit 36 and DUT 26 are serial communications. First interface circuit 24 may be configured to convert serial data from test instrument 16n to parallel data for processing by circuitry 38, and to convert parallel data from circuitry 38 to serial data for output to test instrument 16n. Likewise, second interface second circuit 36 may be configured to convert serial data from DUT 26 to parallel data for processing by circuitry 38, and to convert parallel data from circuitry 38 to serial data for output to DUT 26. Conversion of serial data to parallel data that is processed by circuitry 38 enables circuitry 38 to process more bits at lower speed than had the data remained in serial form.

In some implementations, each interface circuit 34, 36 includes a respective serializer/deserializer (serdes) 40, 42. Serdes 42 is configured to receive serial data from DUT 26 and to convert that serial data to parallel data for output to circuitry 38. Serdes 42 is configured to receive parallel data from circuitry 38 and to convert that parallel data to serial data for output to DUT 26. Serdes 40 is configured to receive serial data from test instrument 16n and to convert that serial data to parallel data for output to circuitry 38. Serdes 40 is configured to receive parallel data from circuitry 38 and to convert that parallel data to serial data for output to test instrument 16n. In some implementations, the serdes may include multiple analog-to-digital converters (ADCs) 44, which are shown as part of second interface circuit 36.

In some implementations, the first protocol used for communication between test instrument 16n and first interface circuit 34 and the second protocol used for communication between DUT 26 and second interface circuit 36 are known, or predefined, protocols. For example, circuitry 38 may be configured to perform conversion between these known protocols. In examples, circuitry 38 may be designed, programmed, or physically or electrically changed or otherwise configured to perform conversion between these protocols. In an example where circuitry 38 includes a processing device or programmable logic, that processing device or programmable logic may be programmed, or reprogrammed, to perform conversion between two predefined protocol. The protocols may be known, prior to testing, to be used for communication with test instrument 16n and with DUT 26. In some implementations, one or both of the protocols may be changed, e.g., through reconfiguration such as reprogramming.

In some implementations, testing may be performed proximate to, or on, probe card 14. For example, probe card 14 may be packaged 46 with a testing device, such as a parametric measurement unit (PMU) 48. For example, a first silicon module may contain interface circuits 34, 36 and circuitry 38 and a second silicon module may contain PMU 48. These two silicon modules may be packaged together using known packaging techniques such that the two constitute single chip or device.

A switch 50 or other device, which may be part of second interface circuit 36 or between second interface circuit 36 and circuitry 38, may be controllable (e.g., by the test instrument) to route data to the on-board PMU 48 to analyze received test data. Results of the analysis may be sent to the test instrument via second interface circuit 36 or via another communication connection between test instrument 16n and package 46 (not shown).

Referring back to FIG. 1, example test system 10 also includes a control system 52. Control system 52 may be configured—e.g., programmed—to communicate with test instruments 16a to 16n to direct and/or to control testing of DUTs, such as, but not limited to, DUT 26. In some implementations, this communication 54 may be over a computer network or via a direct connection such as a computer bus or an optical medium. In some implementations, the computer network may be or include a local area network (LAN) or a wide area network (WAN).

Control system 52 may be or include a computing system comprised of one or more processing devices 56 (e.g., microprocessor(s)) and memory 58 for storing machine-executable instructions 60 to control operation of test system 10 and/or testing, and/or to execute one or more test programs, and/or to send to one or more of the test instruments 16a to 16n for execution. Control system 52 may also be configured to receive and to process data from test instruments 16a to 16n to determine whether DUT 26 and/or one or more other DUTs (not shown) passed testing. For example, one or more processing devices 56 may execute instructions to compare data from a test instrument to one or more thresholds and to determine, based on the comparison, whether a corresponding DUT passed for failed testing.

In some implementations, the control functionality of the control system is centralized in processing device(s) 56. In some implementations, all or part of the control functionality attributed to control system 52 may also or instead be implemented on one or more test instruments 16a to 16n and/or all or part of the testing functionality attributed to one or more test instruments 16a to 16n may also or instead be implemented on control system 52. For example, the control system may be distributed across processing device(s) 56 and one or more of test instruments 16a to 16n.

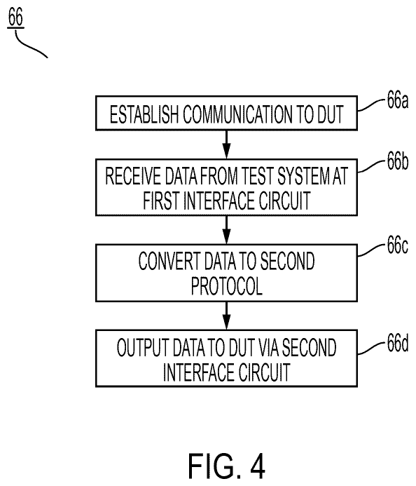

FIG. 4 shows example operations included in an example process 66 that may be performed using the example hardware show in FIGS. 1 to 3. Process 66 may be controlled by control system 52, a test instrument 16n, or control system 52 in combination with one or more of test instruments 16a to 16n.

Process 66 includes establishing (66a) communication between probe card 14 and DUT 26. This may be done by bringing needle 28 into physical contact with a corresponding pin or contact of DUT 26 and/or by creating a wireless link between probe card 14 and DUT 26. The wireless link may be created by virtue of proximity of the probe card and the DUT and/or the wireless link may be established based on signals from the test instrument and/or control system.

Process 66 includes first interface circuit 34 receiving (66b) data from test instrument 16n. This data may be serial test data included in a signal output over long-haul connection 24 from AWG 22. The serial test data may be in a long-haul protocol, such as that described above. First interface circuit 34 provides the data to circuitry 38 for processing. In an example, serdes 40 in first interface circuit 34 samples data from the received signals and generates parallel data for output to circuitry 38. The parallel data remains in the protocol—e.g., the long-haul protocol—used by the test instrument 16n to communicate with the probe card.

Circuitry 38 receives the parallel data and converts (66c) the parallel data into parallel data having a different protocol—e.g., the short-haul protocol—used by DUT 26. Circuitry 38 outputs the parallel data to second interface circuit 36. Second interface circuit 36 outputs (66d) the data in the short-haul protocol to DUT 26 to test the DUT. In an example, serdes 42 in second interface circuit 36 receives the parallel data and generates serial data for output to DUT 26. The serial data remains in the protocol—e.g., the short-haul protocol—used by the DUT 26.

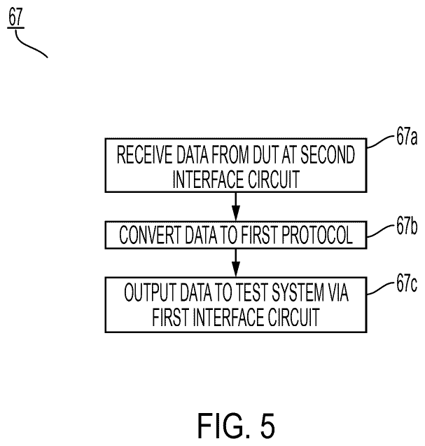

FIG. 5 shows example operations included in an example process 67 that may be performed using the example hardware show in FIGS. 1 to 3. Process 67 may be controlled by control system 52, a test instrument 16n, or control system 52 in combination with one or more of test instruments 16a to 16n.

Process 66 includes second interface circuit 36 receiving (67a) serial response data from DUT 26. This data may represent the DUT's reaction to the test data provided by test instrument 16n in process 66. The serial response data may be in a short-haul protocol, such as that described above. Second interface circuit 36 provides the data to circuitry 38 for processing. In an example, serdes 42 in second interface circuit 36 samples data from received signals and generates parallel data for output to circuitry 38. The parallel data remains in the in the protocol—e.g., the short-haul protocol—used by DUT 26 for communication with probe card 14.

Circuitry 38 receives the parallel data in the short-haul protocol and converts (67b) the parallel data in the short-haul protocol representing the DUT response into parallel data having a different protocol—e.g., the long-haul protocol used by test instrument 16n. Circuitry 38 outputs the parallel data to first interface circuit 34. First interface circuit 34 outputs the data in the long-haul protocol to test instrument 16n. In an example, serdes 40 in first interface circuit 34 receives the parallel data and generates serial data for output (67c) to test instrument 16n. The serial data remains in the in the protocol—e.g., the long-haul protocol—used by instrument 16n.

All or part of the systems and processes described herein including but not limited to processes 66 and 67 and variants thereof may be configured and/or controlled at least in part by one or more computers using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

As used herein, the terms “comprises,” “comprising,” “includes,” “including,” “has,” “having,” “contains,” “containing,” and any variations thereof, are intended to cover a non-exclusive inclusion, such that systems, techniques, apparatus, structures, processes, or other subject matter described or claimed herein that includes, has, or contains an element or list of elements does not include only those elements but can include other elements not expressly listed or inherent to such systems, techniques, apparatus, structures, processes or other subject matter described or claimed herein.

All examples described herein are non-limiting.

In the description and claims provided herein, the adjectives “first”, “second”, “third”, and the like do not designate priority or order unless context suggests otherwise. Instead, these adjectives may be used solely to differentiate the nouns that they modify. Any mechanical or electrical connection herein may include a direct physical connection or an indirect physical connection that includes one or more intervening devices unless context suggests otherwise. A connection between two electrically conductive devices includes an electrical connection unless context suggests otherwise. The signals described herein are electrical signals unless context suggests otherwise.

“Conductive” as used herein refers to electrically conductive unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. An apparatus configured to communicate with a device under test (DUT), the apparatus comprising:
a first interface circuit to communicate with a test instrument using a first protocol;
a second interface circuit to communicate with the DUT using a second protocol, the second protocol being a predefined protocol for which the DUT is configured to operate, the first protocol being for connections associated with a first frequency attenuation, the second protocol being for connections associated with a second frequency attenuation, and the first frequency attenuation being greater than the second frequency attenuation; and
circuitry to perform one or both of the following operations: (i) converting first data received from the test instrument in the first protocol to the second protocol for output to the DUT via the second interface circuit, or (ii) converting second data received from the DUT in the second protocol to the first protocol for output to the test instrument via the first interface circuit.

2. The apparatus of claim 1, wherein the first frequency attenuation is based on an S21 parameter associated with the test instrument and the second frequency attenuation is based on an S21 parameter associated with the DUT.

3. The apparatus of claim 1, wherein the first frequency attenuation is an order of magnitude greater than the second frequency attenuation.

4. The apparatus of claim 1, wherein connections associated with a first frequency attenuation have a length of one meter (m) or more and connections associated with a second frequency attenuation have a length of 30 centimeters (cm) or less.

5. The apparatus of claim 1, wherein connections associated with a first frequency attenuation have a length of one meter (m) or more and connections associated with a second frequency attenuation have a length of 3 centimeters (cm) or less.

6. The apparatus of claim 1, wherein the circuitry is programmable; and
wherein the circuitry is programmed to perform conversions between the first protocol and the second protocol.

7. The apparatus of claim 6, wherein the circuitry comprises one or more of a microprocessor or programmable logic.

8. The apparatus of claim 1, wherein the circuitry comprises multiple analog to digital converters.

9. The apparatus of claim 1, wherein the apparatus is part of a probe card configured to electrically connect to electrical pins on the DUT.

10. The apparatus of claim 1, wherein the apparatus is a needle of a probe card configured to electrically connect to an electrical pin on the DUT.

11. The apparatus of claim 1, wherein the second protocol comprises MIPI (Mobile Industry Processor Interface).

12. The apparatus of claim 1, wherein the second protocol comprises UCIe (Universal Chiplet Interconnect Express).

13. The apparatus of claim 1, wherein the second protocol comprises a radio frequency (RF) protocol.

14. The apparatus of claim 1, wherein the circuitry comprises a serializer/deserializer circuit configured to convert parallel second data to serial first data.

15. The apparatus of claim 1, further comprising:
a switch configured to connect to a parametric measurement unit (PMU) configured to measure one or more properties of a signal.

16. The apparatus of claim 14, further comprising the PMU.

17. The apparatus of claim 14, wherein the apparatus is a package comprising:
a first silicon module comprising the first interface, the second interface, the circuitry, and the switch; and
a second silicon module comprising the PMU.

18. The apparatus of claim 1, wherein the circuitry is configured to perform one of more operations on at least one of the first data or the second data, the one or more comprising: payload extraction, data aggregation, or frame averaging.

19. A method comprising performing at least one of the following first operations or the following second operations:
wherein the first operations comprise:
receiving, at a first interface circuit, first data from a test instrument, the first data having a first protocol;
converting the first data having the first protocol into first data having a second protocol, the second protocol being a known protocol, the first protocol being for connections associated with a first frequency attenuation, the second protocol being for connections associated with a second frequency attenuation, and the first frequency attenuation being greater than the second frequency attenuation; and
outputting, via a second interface circuit, the first data having the second protocol to a device under test (DUT); and
wherein the second operations comprise:
receiving, at the second interface circuit, second data from the DUT, the second data having the second protocol;
converting the second data having the second protocol into second data having the first protocol; and
outputting, via the first interface circuit, the second data having the first protocol to the test instrument.

20. The method of claim 19, wherein the first frequency attenuation is based on an S21 parameter associated with the test instrument and the second frequency attenuation is based on an S21 parameter associated with the DUT.

21. The method of claim 19, wherein the first frequency attenuation is an order of magnitude greater than the second frequency attenuation.

22. The method of claim 19, wherein connections associated with a first frequency attenuation have a length of one meter (m) or more and connections associated with a second frequency attenuation have a length of 30 centimeters (cm) or less.

23. The method of claim 19, wherein connections associated with a first frequency attenuation have a length of one meter (m) or more and connections associated with a second frequency attenuation have a length of 3 centimeters (cm) or less

24. The method of claim 19, wherein the first interface circuit and the second interface circuit are on a probe or probe needle; and
wherein the method further comprises bringing at least part of the probe or the probe needle into electrical contact with the DUT.
